(19) United States
(12) Patent Application Publication
(10) Pub. No.: US 2010/0282711 A1
(43) Pub. Date: Nov. 11, 2010

(54) PROCESS MONITORING APPARATUS AND METHOD

(76) Inventors: Chin-Wook Chung, Seoul (KR); Minhyong Lee, Seoul (KR); Sung-Ho Jang, Seoul (KR); Ik-Jin Choi, Seoul (KR); Jung-Hyung Kim, Daejon (KR); Yong-Hyeon Shin, Daejon (KR)

Correspondence Address: JENKINS, WILSON, TAYLOR & HUNT, P. A., 3100 Tower Blvd., Suite 1200, DURHAM, NC, 27707, US

(21) Appl. No.: 12/744,723

(22) PCT Filed: Dec. 12, 2008
(86) PCT No.: PCT/KR2008/007367

§ 371 Date: May 26, 2010

(30) Foreign Application Priority Data
Dec. 20, 2007 (KR) 10-2007-0134192

(51) Int. Cl. C23F 1/08; C23C 16/52; C23F 1/00

(52) U.S. Cl. 216/61; 118/712; 156/345.28; 427/8

(57) ABSTRACT

Provided are a process monitoring apparatus and method. The process monitoring apparatus includes a process chamber in which a process is performed, a probe assembly disposed on the process chamber, and comprising a probe electrode, a plasma generator generating plasma around the probe assembly, and a drive processor applying an alternating current (AC) voltage having at least 2 fundamental frequencies to the probe assembly, and extracting process monitoring parameters.

### TECHNICAL FIELD

The present invention relates to a process monitoring apparatus, and more particularly, to a process monitoring apparatus and method capable of monitoring the state of a process chamber using plasma or the surface state of an exhaust line, characteristics of the plasma, and whether arc discharge occurs.

### BACKGROUND ART

In general, a Langmuir probe is used to measure the electron temperature and electron density of plasma. A Langmuir probe can obtain electron temperature and plasma density by applying a direct current (DC) voltage to a metal that can withstand high temperature, such as tungsten, and analyzing DC voltage-current characteristics. A Langmuir probe using metal may provide incorrect information on plasma or affect the plasma because the metal is etched or impurities are deposited on the metal over time.

During deposition or etch processes, the inner walls of a process chamber can be contaminated. Contaminants may include gases used for deposition or etch processing, gas by-products, or materials that react to gases. Accordingly, the contaminants can reduce process reproducibility. To prevent this from occurring, a cleaning stage is generally included in a deposition or etch process. An optical diagnosis method may be employed to measure the contaminated state inside a chamber during the deposition process or the etch process. However, it is difficult to measure the contaminated state of an inner wall of the process chamber with such an optical diagnosis method. It is also difficult to accurately measure the electron temperature or electron density of plasma.

In addition, particles can be generated from contaminants on the inner wall of a plasma process chamber from deposition or etch processing, or from process by-products of the plasma process chamber. Thus, when plasma process is performed, the particles can trigger arc discharge. Typically, an optical diagnosis method may be used to detect arc discharge. However, to use the optical diagnosis method, a chamber requires a window. The window can be contaminated from performing etch or deposition processes. Therefore, the amount of light transmitted through the window can be reduced when process is performed. Accordingly, the sensitivity of arc monitoring can be reduced.

### DISCLOSURE OF INVENTION

### Technical Problem

The present invention provides a process monitoring apparatus capable of monitoring a surface state of a process chamber during processing by generating plasma directly or indirectly.

The present invention also provides a method for process monitoring capable of monitoring a surface state of a process chamber during processing by generating plasma directly or indirectly.

### Technical Solution

Embodiments of the present invention provide process monitoring apparatuses including a process chamber in which process is performed, a probe assembly disposed on the process chamber, and including a probe electrode, a plasma generator for generating plasma around the probe assembly, and a drive processor for applying an alternating current (AC) voltage having at least 2 fundamental frequencies to the probe assembly, and extracting process monitoring parameters.

In some embodiments, the drive processor may include a driver for applying an AC voltage having at least 2 fundamental frequencies to the probe electrode, a sensor for measuring a probe current flowing in the probe electrode, and a processor for extracting harmonic components of each fundamental frequency of the probe current, wherein the processor may process the harmonic components of each of the fundamental frequencies to extract process monitoring parameters.

In other embodiments, the process monitoring parameters may include at least one of components of equivalent circuits formed by the plasma and the probe assembly, physical quantities relating to characteristics of the plasma, and physical quantities relating to a surface state of the probe electrode.

In still other embodiments, the fundamental frequencies of the AC voltage may include a first fundamental frequency and a second fundamental frequency, and the processor may include a frequency processor configured to extract a Fourier series coefficient of the first fundamental frequency of the probe current and a Fourier series coefficient of the second fundamental frequency of the probe current, and a data processor configured to extract the process monitoring parameters through using the Fourier series coefficient of the first fundamental frequency and the Fourier series coefficient of the second fundamental frequency.

In yet other embodiments, the data processor may extract the process parameters through using a first Fourier series coefficient of the first fundamental frequency and a first Fourier coefficient of the second fundamental frequency.

In further embodiments, the data processor may be configured to extract the equivalent circuit components through using the first Fourier series coefficient of the first fundamental frequency and the first Fourier series coefficient of the second fundamental frequency, and may be configured to extract the physical quantities relating to the characteristics of the plasma through using the first Fourier series coefficient of the first fundamental frequency and a second Fourier series coefficient of the first fundamental frequency, or the first Fourier series coefficient of the second fundamental frequency and a second Fourier series coefficient of the second fundamental frequency.

In still further embodiments, the data processor may be configured to extract the equivalent circuit components through using the first Fourier series coefficient of the first fundamental frequency and the first Fourier series coefficient of the second fundamental frequency, and may be configured to extract the physical quantities relating to the characteristics of the plasma through using the first Fourier series coefficient of the first fundamental frequency and the first Fourier series coefficient of the second fundamental frequency.

In even further embodiments, the probe assembly may further include an insulating protective layer that separates the probe electrode from the plasma, and the sensor may further include a compensator that compensates for a capacitance of the insulating protective layer in terms of a circuit.

In yet further embodiments, the drive processor may include a driver for applying an AC voltage having at least two fundamental frequencies to the probe electrode, a sensor for measuring a probe current flowing in the probe electrode, and an arc processor for processing the probe current and determining whether an arc is discharged in the plasma.

In some embodiments, the drive processor may be configured to extract at least one of a capacitance and a sheath resistance between the probe assembly and the plasma.

In other embodiments, the process monitoring apparatus may further include at least one of a capacitor between the probe assembly and the drive processor, and an insulating protective layer on the probe electrode.

In still other embodiments, the probe assembly may include a first probe electrode and a second probe electrode, and a first fundamental frequency may be applied to the first probe electrode, and a second fundamental frequency may applied to the second probe electrode.

In yet other embodiments, the probe assembly may include a first probe electrode and a second probe electrode, and a first and a second fundamental frequency may be applied to the first probe electrode, and the second probe electrode may be grounded.

In further embodiments, the drive processor may be configured to monitor a change in process monitoring parameters through a thin film formed on the probe electrode.

In still further embodiments, the process chamber may include a first region in which process is performed and a second region connected to an exhaust pump, wherein the plasma generator may generate plasma in the first region or the second region.

In even further embodiments, a an AC voltage having at least 2 fundamental frequencies may be applied to the probe electrode using at least one of a method of increasing a frequency continuously over time, a method of applying AC voltages including respectively different frequencies at respectively different points in time, and a method of simultaneously applying a plurality of fundamental frequencies.

In other embodiments of the present invention, process monitoring methods include providing a probe assembly including a probe electrode to a process chamber, generating plasma around the probe assembly, and applying an alternating current (AC) voltage having at least two fundamental frequencies to the probe assembly, and extracting process monitoring parameters.

In some embodiments, the extracting of the process monitoring parameters may include applying an AC voltage having at least two fundamental frequencies to the probe electrode, measuring a probe current flowing in the probe electrode, and extracting harmonic frequencies of respective fundamental frequencies of the probe current flowing in the probe electrode, and processing the harmonic frequencies to extract process monitoring parameters.

In other embodiments, the process monitoring parameters may include at least one of components of equivalent circuits formed by the plasma and the probe assembly, physical quantities relating to characteristics of the plasma, and physical quantities relating to a surface state of the probe electrode.

In still other embodiments, the fundamental frequencies of the AC voltage may include a first fundamental frequency and a second fundamental frequency, and the extracting of the process monitoring parameters may include extracting a Fourier series coefficient of the first fundamental frequency of the probe current and a Fourier series coefficient of the second fundamental frequency of the probe current, and extracting the process monitoring parameters through using the Fourier series coefficient of the first fundamental frequency and the Fourier series coefficient of the second fundamental frequency.

In yet other embodiments, the extracting of the process monitoring parameters through using the Fourier series coefficient of the first fundamental frequency and the Fourier series coefficient of the second fundamental frequency may include extracting the process monitoring parameters through using a first Fourier series coefficient of the first fundamental frequency and a first Fourier coefficient of the second fundamental frequency.

In further embodiments, the extracting of the process monitoring parameters through using the Fourier series coefficient of the first fundamental frequency and the Fourier series coefficient of the second fundamental frequency may include extracting the equivalent circuit components through using the first Fourier series coefficient of the first fundamental frequency and a second Fourier series coefficient of the first fundamental frequency, and extracting the physical quantities relating to the characteristics of the plasma through using the first Fourier series coefficient of the second fundamental frequency and a second Fourier series coefficient of the second fundamental frequency.

In still further embodiments, the extracting of the process monitoring parameters through using the Fourier series coefficient of the first fundamental frequency and the Fourier series coefficient of the second fundamental frequency may include extracting the equivalent circuit components through using the first Fourier series coefficient of the first fundamental frequency and the first Fourier series coefficient of the second fundamental frequency, and extracting the physical quantities relating to the characteristics of the plasma through using the first Fourier series coefficient of the first fundamental frequency and the first Fourier series coefficient of the second fundamental frequency.

In even further embodiments, the extracting of the process monitoring parameters may include processing a probe current flowing in the probe assembly to determine an end point of an etching.

In yet further embodiments, the extracting of the process monitoring parameters may include processing a probe current flowing in the probe assembly, and treating a deviation of the probe current from a normal state as an arc discharge.

In further embodiments of the present invention, process monitoring apparatuses include a probe assembly including a probe electrode, and a drive processor for applying an alternating current (AC) voltage having at least 2 fundamental frequencies to the probe assembly, and extracting process monitoring parameters.

In some embodiments, the drive processor may include a driver applying an AC voltage having at least 2 fundamental frequencies to the probe electrode, a sensor for measuring a probe current flowing in the probe electrode, and a processor for extracting harmonic components for each of the fundamental frequencies of the probe current, wherein the processor may process the harmonic components for the respective fundamental frequencies to extract the process monitoring parameters.

In other embodiments, the process monitoring apparatus may further include at least one of a capacitor between the probe assembly and the drive processor, and an insulating protective layer on the probe electrode.

### ADVANTAGEOUS EFFECTS

In the probe assembly of the present invention, even when the surface state of the probe assembly changes when a process is performed, process monitoring can be performed by measuring the surface state of the probe assembly, plasma characteristics, and arc generation.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is an equivalent circuit diagram illustrating a junction between plasma and a probe assembly according to an embodiment of the present invention;

FIG. 2 is an equivalent circuit diagram illustrating a junction between plasma and a probe assembly according to an embodiment of the present invention;

FIGS. 3 and 4 are conceptual views illustrating a process monitoring apparatus according to an embodiment of the present invention;

FIG. 5 is a conceptual view of a process monitoring apparatus according to an embodiment of the present invention;

FIG. 6 is conceptual view of a drive processor according to an embodiment of the present invention;

FIG. 7 is a conceptual view of a processor according to an embodiment of the present invention;

FIG. 8 is a block diagram illustrating a data processor according to an embodiment of the present invention;

FIGS. 9 through 22 are diagrams illustrating a probe assembly according to an embodiment of the present invention;

FIGS. 23 through 25 are block diagrams illustrating a sensor according to an embodiment of the present invention;

FIG. 26 is a diagram illustrating a compensator for calibrating a measurement signal of a sensor according to an embodiment of the present invention;

FIG. 27 is a circuit diagram illustrating a filter for removing noise according to an embodiment of the present invention;

FIGS. 28 and 29 are diagrams illustrating a frequency processor according to an embodiment of the present invention;

FIG. 30 is a block diagram illustrating a process monitoring apparatus according to an embodiment of the present invention;

FIG. 31 is a block diagram illustrating a process monitoring apparatus according to another embodiment of the present invention; and

FIGS. 32 through 35 are flowcharts illustrating process monitoring methods according to embodiments of the present invention.

### BEST MODE FOR CARRYING OUT THE INVENTION

A process chamber can be contaminated in a semiconductor manufacturing process, a liquid crystal display (LCD) manufacturing process, a material surface treatment, etc. There are various causes for such contamination. For example, within a plasma treatment apparatus, process gas, by-products, reaction materials, plasma, neutral atoms, neutral molecules, and materials on a substrate may contaminate walls of a process chamber or may etch the walls of the chamber. For instance, in the case of plasma etch processing, a material that contaminates walls of a process chamber may be a CFx-based polymer. In a deposition process, gas used for deposition may contaminate the walls of a process chamber. In the case of deposition, contaminants deposited on the walls of the process chamber may include polymers, insulators, conductors, and semiconductors, according to the type of deposited material. Also, the contaminants on the walls of the process chamber may include a material formed on a substrate.

For example, in the cases of a deposition process or an etch process that use plasma, the characteristics of plasma may change because the plasma depends on the degree of contamination according to the processing time. Therefore, reproducibility of an etch process or a deposition process can be reduced. Also, when contaminants deposited on the walls of the process chamber are desorbed from the walls of the process chamber and deposited on the surface of a substrate, this can lead to device defects. Furthermore, contaminants that are released from the walls of a process chamber during plasma processing form particles that can trigger arc discharge. This phenomenon is dependent on changes in the environment within the process chamber over time. There is thus a need to monitor changes in the environment within a process chamber.

For this end, the present invention employs a probe assembly including a probe electrode improved over the existing Langmuir probe to monitor the environment within a process chamber during processing. The probe assembly may be disposed on a surface such as a wall of the process chamber. When an insulating protective layer on the probe electrode is formed of a material similar to that constituting the process chamber, the surface state of the insulating protective layer can indicate the surface state of the walls of the process chamber. For example, the degree that the probe assembly has been etched, the surface state of the probe assembly, and the degree of thin film deposition on the surface of the probe assembly can be determined. Also, when the process uses plasma, the electron density and electron temperature of the plasma can be monitored.

The present invention requires plasma for process monitoring, and the plasma may be generated to perform the processing, or the plasma may be generated for measuring the surface state of the probe assembly, regardless of the processing. Accordingly, the applicable scope of the present invention is not limited to only processes that use plasma, and can be applied to any apparatus for which contamination of a process chamber presents a problem.

In general, an etch process and a deposition process contaminate walls of a process chamber, so that the etch process and the deposition process may include a main process and a cleaning process. The main process may be a process of performing the actual etching or deposition on a substrate, and the cleaning process may be a process of preparing the environment of the walls of the process chamber in order to ensure process reproducibility. The present invention may be applied to a main process that uses plasma. The present invention may also be applied to a cleaning process using plasma. The present invention can monitor processing in real time. Therefore, the apparatus of the present invention may be used as a counter for determining processing time for a cleaning process. The present invention is not limited to having the probe assembly directly attached to a process chamber, but may include the probe assembly installed on an exhaust line. For example, the process monitoring apparatus of the present invention may be attached to an exhaust line of a chemical vapor deposition (CVD) apparatus or a surface treatment apparatus that does not use plasma, and plasma may be generated to operate the process monitoring apparatus. A plasma generator may generate plasma in pulse mode or in continuous mode to operate the process monitoring apparatus of the present invention. The plasma generator may include a capacitively coupled plasma apparatus, an inductively coupled plasma apparatus, an micowave plasma apparatus, a DC plasma apparatus, an AC plasma apparatus, or any other plasma apparatus.

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of electrodes, films, layers and regions are exaggerated for clarity of illustration. It will also be understood that when a layer (or film) is referred to as being ‘on’ another layer or electrode, it can be directly on the other layer or electrode, or intervening layers may also be present. Like reference numerals refer to like elements throughout. In the description, the term ‘frequency’ may be used interchangeably for waves and oscillation over unit time. Also, the terms ‘angular frequency’ and ‘frequency’ may be interchangeably used. The angular frequency differs from the frequency by a coefficient difference of 2π.

A description of the operating principle of the present invention will be given. A probe assembly includes a probe electrode, and the probe electrode may directly or indirectly contact plasma. The probe assembly is electrically floated, and an insulating protective layer may be disposed between the probe electrode and plasma, or a capacitor may be disposed between the probe electrode and a driver that applies a voltage to the probe electrode. The insulating protective layer on the probe electrode may perform the function of a capacitor.

When a capacitor is disposed between a driver that applies a voltage (V(t)) to the probe electrode and the probe electrode, and the probe electrode is floated, a probe current (iₚ) that flows through the probe assembly can be represented with two terms, i.e., an electron current and an ion current, and may be expressed as Eq. 1.

$$\begin{matrix} MathFigure 1 & \\ {i}_{p} ( t ) = {i}_{es} e \text{?} - {i}_{is} \\ \text{?} \text{indicates text missing or illegible when filed} & [ Math . 1 ]\end{matrix}$$

Here, the ion saturation current, iᵢₛ, may be dependent on ion density and Bohm speed. The Bohm speed may depend on electron temperature. The electron density and ion density in plasma can be said to be the same, and plasma density generally denotes electron density. Electron saturation current iₑₛ may be dependent on electron density, nₑ, and average speed of electrons. Plasma potential (Vₚ) is the electric potential of plasma. The voltage (V(t)) of the probe electrode may vary over time. The electron temperature, Tₑ, is determined by an electron energy distribution function. The voltage (V(t)) of the probe electrode varies over time, and may have at least 2 fundamental frequencies.

A voltage applied to the probe electrode according to an embodiment of the present invention is a cosine (COS) function of a fundamental frequency over time, and the voltage of the probe electrode may be expressed as Eq. 2.

MathFigure 2

V(t)=V_{f}+v cos ω₀t, 0<t<τ [Math.2]

where V_{f} is an offset value or a DC bias value, ω₀ is a fundamental frequency (or an angular frequency), and v₀ is an amplitude of an applied voltage of the probe electrode. A probe current that flows through the probe electrode over time may be expressed as a Fourier transformation in a frequency domain. That is, Eq. 3 can be derived.

$$\begin{matrix} MathFigure 3 & \\ \begin{matrix} {i}_{p} ( t ) = {i}_{es} e \text{?} e \text{?} - {i}_{is} \\ = \text{?} \text{?} {I}_{p , n} e \text{?}\end{matrix} & [ Math . 3 ] \\ \begin{matrix} {I}_{p , n} = \frac{1}{τ} [ {\int }_{0}^{I} {i}_{p} ( t ) e \text{?} ] \\ = {i}_{es} e \text{?} \frac{1}{τ} [ {\int }_{0}^{I} e \text{?} cos n {ω}_{0} d t - j {\int }_{0}^{I} e \text{?} sin n {ω}_{0} d t ]\end{matrix} & \\ {I}_{n} ( \frac{{v}_{0}}{{T}_{e}} ) = \frac{1}{τ} [ {\int }_{0}^{I} e \text{?} cos n {ω}_{0} d t ] , \\ 0 = \frac{1}{τ} [ {\int }_{0}^{I} e \text{?} sin n {ω}_{0} d t ] \\ \text{?} \text{indicates text missing or illegible when filed} & \end{matrix}$$

where n is an integer, τ is a period, I_{p,n} is a Fourier series coefficient, and Iₙ is a modified Bessel function. In the case where n=0, in a frequency domain, a DC Fourier series coefficient (I_{p,0}) may be derived as Eq. 4. While the probe electrode current has been expanded in terms of a Fourier series, it may be expanded through another method including harmonics.

$$\begin{matrix} MathFigure 4 & \\ {I}_{p , 0} = {i}_{es} e \text{?} {I}_{0} ( \frac{{v}_{0}}{{T}_{e}} ) - {i}_{is} \\ \text{?} \text{indicates text missing or illegible when filed} & [ Math . 4 ]\end{matrix}$$

When n is not 0, in a frequency domain, a Fourier series coefficient (I_{p,n}) may be derived as Eq. 5.

$$\begin{matrix} MathFigure 5 & \\ {I}_{p , n} = {i}_{es} e \text{?} {I}_{n} ( \frac{{v}_{0}}{{T}_{e}} ) \\ \text{?} \text{indicates text missing or illegible when filed} & [ Math . 5 ]\end{matrix}$$

For symmetry, when n is a positive integer, in a frequency domain, a Fourier series coefficient may be derived as Eq. 6.

$$\begin{matrix} MathFigure 6 & \\ {I}_{n} ( \frac{{v}_{0}}{{T}_{e}} ) = {I}_{- n} ( \frac{{v}_{0}}{{T}_{e}} ) & [ Math . 6 ] \\ {I}_{p , n} = 2 {i}_{es} e \text{?} {I}_{n} ( \frac{{v}_{0}}{{T}_{e}} ) \\ \text{?} \text{indicates text missing or illegible when filed} & \end{matrix}$$

In a floating condition, a DC Fourier series coefficient flowing through the probe electrode can satisfy following Eq. 7.

$$\begin{matrix} MathFigure 7 & \\ {I}_{p , 0} = {i}_{es} e \text{?} {I}_{0} ( \frac{{v}_{0}}{{T}_{e}} ) - {i}_{is} = 0 \\ \text{?} \text{indicates text missing or illegible when filed} & [ Math . 7 ]\end{matrix}$$

Using the above conditions, when a Taylor expansion is performed on a modified Bessel function, a first and a second Fourier series coefficient may be derived as Eq. 8.

$$MathFigure 8$$

$${I}_{p , 1} = 2 {i}_{es} \frac{{I}_{1} ( \frac{{v}_{0}}{{T}_{e}} )}{{I}_{0} ( \frac{{v}_{0}}{{T}_{e}} )} \approx {i}_{is} ( \frac{{v}_{0}}{{T}_{e}} ) , \\ {I}_{p , 2} = 2 {i}_{es} \frac{{I}_{2} ( \frac{{v}_{0}}{{T}_{e}} )}{{I}_{0} ( \frac{{v}_{0}}{{T}_{e}} )} \approx \frac{{i}_{is}}{4} {( \frac{{v}_{0}}{{T}_{e}} )}^{2} , \qquad [ Math . 8 ]$$

Accordingly, the electron temperature (Tₑ) may be dependent on the ratio of the first Fourier series coefficient and the second Fourier series coefficient. Thus, the electron temperature (Tₑ) and the ion saturation current (iᵢₛ) may be derived as Eq. 9.

$$MathFigure 9$$

$${T}_{e} \approx \frac{{v}_{0}}{4} \frac{{I}_{p , 1}}{{I}_{p , 2}} \\ {I}_{is} = {I}_{p , 1} ( \frac{{v}_{0}}{{T}_{e}} ) \approx \frac{1}{4} \frac{{I}_{p , 1}^{2}}{{I}_{p , 2}} \qquad [ Math . 9 ]$$

Accordingly, the electron temperature and the electron density can be derived. While the electron temperature and the electron density have been derived using the first Fourier coefficient and second Fourier coefficient, they are not limited thereto, and may derived using a third-order or higher Fourier coefficient.

The operating principle of the above-described probe electrode can be applied similarly to a case in which there are 2 fundamental angular frequencies, and a detailed description thereof will not be provided. Also, because the operating principle of a probe electrode having the above-described insulating protective layer thereon is similar to the operating principle already described, a detailed description thereof will not be provided.

A probe assembly according to an embodiment of the present invention includes a probe electrode, and a method of inspecting the surface state of the insulating protective layer on the probe electrode will be described.

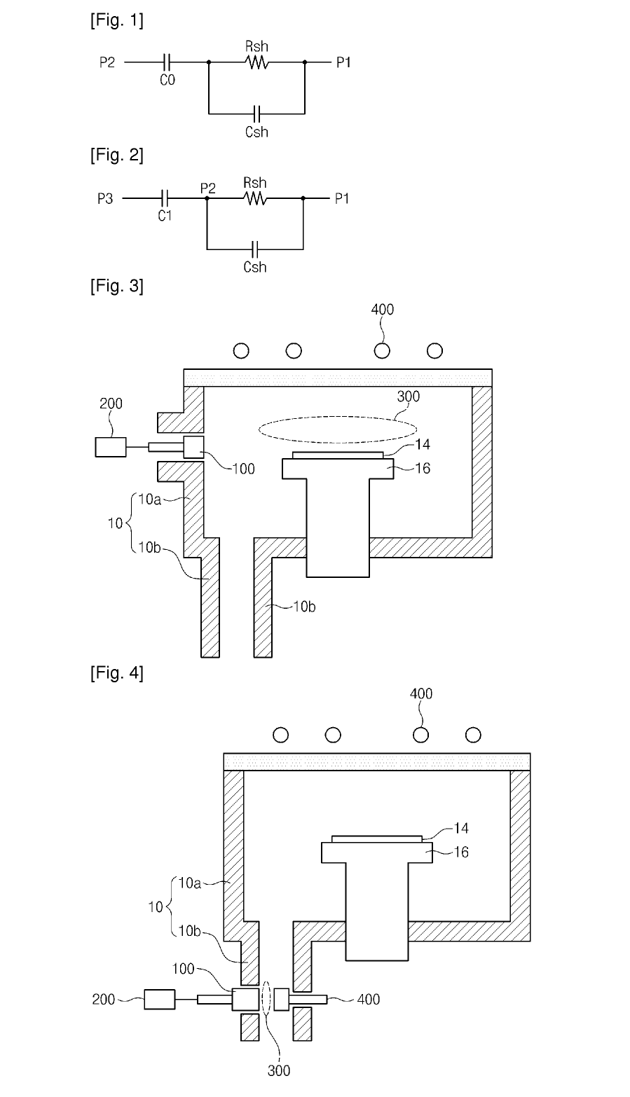

FIG. 1 is an equivalent circuit diagram illustrating a junction between plasma and a probe assembly according to an embodiment of the present invention.

Referring to FIG. 1, P1 represents plasma, and P2 represents a probe electrode. A sheath region is formed between the plasma and the probe assembly. The sheath region may be represented as a parallel connection of a sheath resistance (Rsh) and a sheath capacitance (Csh). Also, when the probe assembly includes an insulating protective layer on a probe electrode, the insulating protective layer forms a capacitor (C0). In a general frequency domain of about 1 MHz or less, impedance that causes sheath capacitance (Csh) may be nominal compared to the sheath resistance (Rsh). Therefore, the equivalent circuit between the plasma and the probe electrode may be represented with a series connection between the capacitor (C0) and the sheath resistance (Rsh). According to modified embodiments of the present invention, the equivalent circuit between the probe assembly and the plasma are not limited to the above-described model, and may be modified in various ways.

When the probe assembly includes an insulating protective layer, a thin film may be deposited on the insulating protective layer, or the insulating protective layer may be etched while a process is performed. Here, an equivalent capacitance (C) between the probe electrode and plasma may be derived. The equivalent capacitance (C) may depend on the surface state (permittivity, thickness, etc.) of the thin film on the insulating protective layer. For example, a thin film may be formed on the surface of the probe assembly disposed inside a process chamber through deposition of process gas, process gas resolvent, plasma, etch by-products, materials etched from a substrate, etc., on the insulating protective layer. The thin film may be an organic film. In this case, the equivalent capacitance (C) between the probe electrode and plasma may change. The equivalent capacitance (C) can provide data on the insulating protective layer and/or on the thin film on the insulating protective layer.

A method of inspecting the surface state of a probe electrode in a probe assembly according to another embodiment of the present invention that includes a probe electrode, will be described.

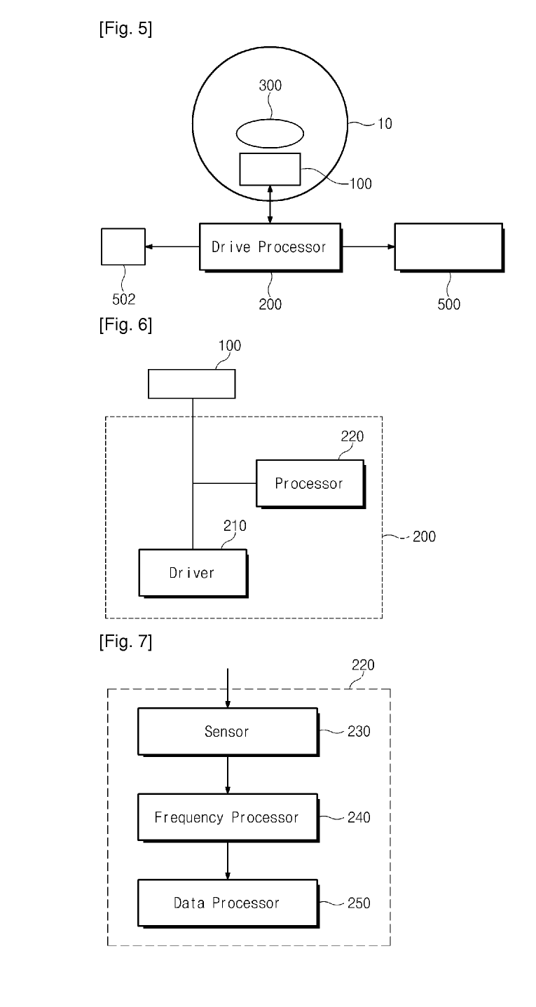

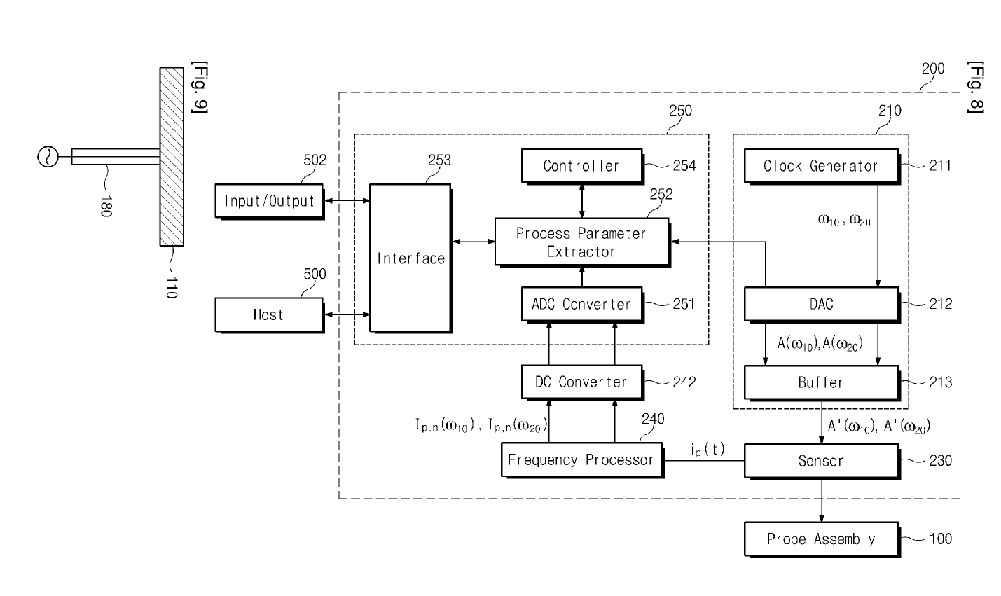

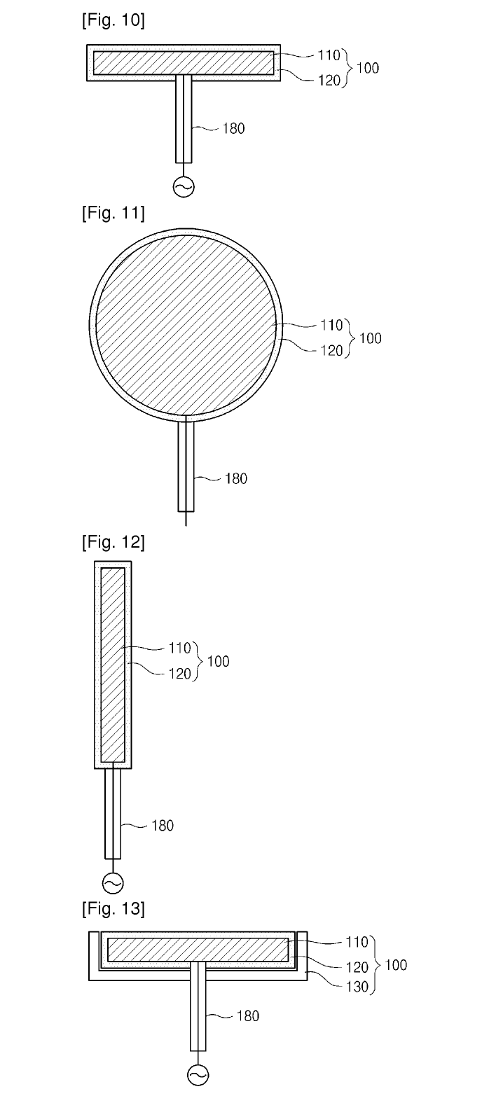

FIG. 2 is an equivalent circuit diagram illustrating a junction between plasma and a probe assembly according to an embodiment of the present invention.

Referring to FIG. 2, P1 represents plasma, and P2 represents a probe electrode. A capacitor (C1) is disposed between the probe electrode and a driving end (P3). A sheath region is formed between the plasma and the probe assembly. The sheath region may be represented as a parallel connection between a sheath resistance (Rsh) and a sheath capacitance (Csh). In a general frequency domain of about 1 MHz or less, impedance that causes sheath capacitance (Csh) may be nominal compared to the sheath resistance (Rsh). Therefore, the equivalent circuit between the plasma and the driving end may be similar to a series connection circuit between the capacitor (C1) and the sheath resistance (Rsh). According to modified embodiments of the present invention, the equivalent circuit between the probe assembly and the plasma are not limited to the above-described model, and may be modified in various ways.

When a thin film is formed on the probe electrode during processing, the equivalent capacitance (C) between the plasma (P1) and the driving end (P3) can provide data on the thin film on the probe electrode.

An alternating current (AC) voltage having at least 2 fundamental frequencies is applied to the probe assembly. Here, the sheath resistance (Rsh) can be approximately derived through following Eq. 10.

$$\begin{matrix}MathFigure 10 & \\ {R}_{sh} \approx \frac{{T}_{e}}{{i}_{is}} & [ Math . 10 ]\end{matrix}$$

A AC voltage having a first fundamental angular frequency, ω₁₀, and an AC voltage having a second fundamental angular frequency, ω₂₀, are applied to the probe electrode. Here, the amplitude, v_{1,0}, of an applied voltage of the first fundamental angular frequency and an amplitude, v_{2,0}, of an applied voltage of the second fundamental angular frequency may fall in a range of about several volts. For example, a description will be provided of the handling of when the first and the second fundamental angular frequencies are simultaneously applied to the probe electrode. When the probe assembly includes an insulting protective layer, a voltage applied to the sheath resistance may be calculated using an impedance voltage division principle. A first Fourier series coefficient expanded using a first fundamental angular coefficient, and a first Fourier series coefficient expanded from a second fundamental angular coefficient may be calculated with reference to Equation 8. Therefore, the equivalent capacitance (C) may be calculated as Eq. 11.

$$MathFigure 11$$

$$C = \frac{ɛ A}{d} = f ( {ω}_{10} , {ω}_{20} , {v}_{1 , 0} , {v}_{2 , 0} , {I}_{p , 1} ( {ω}_{10} ) , {I}_{p , 1} ( {ω}_{20} ) ) \qquad [ Math . 11 ]$$

The equivalent capacitance (C) may be proportional to an area (A) at which the probe electrode and the plasma face each other, may be proportional to the permittivites (∈) of the insulating protective layer and the thin film, and may be inversely proportional to the thicknesses (d) of the insulating protective layer and the thin film. In general, because the area (A) and the thickness of the insulating protective layer are known values, the state of the thin film can be determined. Specifically, when the thin film is formed during processing, the thickness of the thin film that is converted to the vacuum permittivity can be determined in real time.

In detail, the sheath resistance can be derived as Eq. 12.

MathFigure 12

Rₛₕ=h(ω₁₀,ω₂₀,v_{1,0},v_{2,0},I_{p,1}(ω₁₀),I_{p,1}(ω₂₀)) [Math.12]

By measuring the sheath resistance (Rsh), the state of the thin film can be monitored. The probe assembly may be changed to various configurations when floated. In this case, the above-described principles may be similarly applied.

According to alternative embodiment of the present invention, a probe assembly may have a probe electrode, and a conductive material may be deposited on the probe electrode during processing to form a thin film. In particular, the thin film may be deposited through sputtering a target in a process chamber, or formed through chemically reacting a process gas on the probe electrode. The thin film having conductivity may be treated as an equivalent circuit in which a resistor and a capacitor are connected in series. In this case, the equivalent resistance and equivalent capacitance of the thin film, and the sheath resistance can be obtained similarly to the method described above. To extract all the components of the equivalent circuit, 3 or more fundamental frequencies may be used.

According to the embodiment of the present invention, a method for measuring electron temperature, ion saturation current, and electron density will be described. As described above, when a probe current flowing through a probe assembly is expanded through a Fourier series, a first Fourier series coefficient on each of the fundamental frequencies is derived as Eq. 13.

$$\begin{matrix} MathFigure 13 & \\ \begin{matrix} I \text{?} ( {ω}_{10} ) = 2 i \text{?} \frac{{I}_{1} ( {v}_{1} / T \text{?} )}{{I}_{0} ( {v}_{1} / T \text{?} )} \approx i \text{?} ( \frac{{v}_{1}}{\text{?}} - \frac{1}{8} {( \frac{{v}_{1}}{\text{?}} )}^{3} ) \\ I \text{?} ( {ω}_{20} ) = 2 i \text{?} \frac{{I}_{1} ( {v}_{2} / T \text{?} )}{{I}_{0} ( {v}_{2} / T \text{?} )} \approx i \text{?} ( \frac{{v}_{2}}{\text{?}} - \frac{1}{8} {( \frac{{v}_{2}}{\text{?}} )}^{3} ) \\ \text{?} \text{indicates text missing or illegible when filed}\end{matrix} & [ Math . 13 ]\end{matrix}$$

where v₁ and v₂ are the amplitudes of a first fundamental angular frequency, ω₁₀, and a second fundamental angular frequency, ω₂₀, respectively, applied to the sheath resistance when an insulating protective layer is provided. Using resistance (R) and capacitance (C), v₁ and v₂ can be obtained. Electron temperature (Te) can be obtained using a ratio (ν) of a first Fourier series coefficient of the first fundamental angular frequency and a first Fourier series coefficient of the second fundamental angular frequency. The ratio (ν) is expressed as Eq. 14.

$$MathFigure 14$$

$$γ = \frac{{I}_{p , 1} ( {ω}_{10} )}{{I}_{p , 1} ( {ω}_{20} )} ⇒ {T}_{e} = \frac{1}{2} \sqrt{\frac{γ {v}_{2}^{3} - {v}_{1}^{3}}{2 ( γ {v}_{2} - {v}_{1} )}} \qquad [ Math . 14 ]$$

An ion saturation current (iₑₛ) may be expressed through the first Fourier series coefficient of the first fundamental angular frequency or the first Fourier series coefficient of the second fundamental angular frequency, as following Eq. 15.

$$MathFigure 15$$

$${i}_{is} \approx \frac{{I}_{p , 1} ( {ω}_{10} )}{\frac{{v}_{1}}{{T}_{e}} - \frac{1}{8} {( \frac{{v}_{1}}{{T}_{e}} )}^{3}} \\ {i}_{is} \approx \frac{{I}_{p , 1} ( {ω}_{20} )}{\frac{{v}_{2}}{{T}_{e}} - \frac{1}{8} {( \frac{{v}_{2}}{{T}_{e}} )}^{3}} \qquad [ Math . 15 ]$$

The ion saturation current (iₑₛ) is a function of the electron temperature and the ion density, so that the ion density or the electron density can be obtained.

According to an alternative embodiment of the present invention, as described with Equation 9, the electron temperature (Te) and the electron density can be obtained using the first Fourier series coefficient and second Fourier series coefficient of the fundamental frequency, respectively. By using resistance (R) and capacitance (C), v₁ and v₂ can be obtained. Specifically, as already described, electron temperature and ion saturation current can be expressed as Eq. 16.

$$MathFigure 16$$

$${T}_{e} \approx \frac{{v}_{1}}{4} \frac{{I}_{p , 1} ( {ω}_{10} )}{{I}_{p , 2} ( {ω}_{10} )} \approx \frac{{v}_{2}}{4} \frac{{I}_{p , 1} ( {ω}_{20} )}{{I}_{p , 2} ( {ω}_{20} )} \\ {i}_{is} = {I}_{p , 1} ( {ω}_{20} ) ( \frac{{v}_{2}}{{T}_{e}} ) \approx \frac{1}{4} \frac{{I}_{p , 1}^{2} ( {ω}_{20} )}{{I}_{p , 2} ( {ω}_{20} )} \qquad [ Math . 16 ]$$

where v₁ and v₂ are amplitudes applied to the sheath resistance of the respective fundamental frequencies, I_{p,1}(ω₁₀) is the first Fourier series coefficient of the first fundamental angular frequency, and I_{p,2}(ω₁₀) is the second Fourier series coefficient of the first fundamental angular frequency. I_{p,1}(ω₂₀) is the first Fourier series coefficient of the second fundamental angular frequency, and I_{p,2}(ω₂₀) is the second Fourier series coefficient of the second fundamental angular frequency.

FIGS. 3 and 4 are conceptual views illustrating a process monitoring apparatus according to an embodiment of the present invention.

Referring to FIG. 3, the process monitoring apparatus includes a probe assembly 100 with a probe electrode disposed in a process chamber 10 in which a process is performed, a plasma generator 400 that generates plasma 300 around the probe assembly 100, and a drive processor 200 that applies an AC voltage with at least two fundamental frequency components to the probe assembly 100 and that processes current flowing in the probe assembly 100. The process chamber 10 may include a first region 10a in which a process is performed, and a second region 10b connected to an exhaust pump. The second region 10b may include an exhaust line.

The process chamber 10 may perform at least one process from an etch process, a deposition process, an ion implantation process, and a surface treatment process. A substrate holder 16 and a substrate 14 may placed at the inside of the first region 10a. Material inside the first region 10a may be exhausted through the second region 10b. Material coated on the inner surface of the first region 10a may be the same material as that on the surface of the probe assembly.

The plasma generator 400 may include at least one of an inductively coupled plasma generating apparatus, a capacitively coupled plasma generating apparatus, an AC plasma generating apparatus, a DC plasma generating apparatus, and an ultra high frequency plasma generating apparatus. The plasma generator may be configured to operate in at least one of continuous mode or pulse mode.

The probe assembly 100 is connected to the drive processor 200. The drive processor 200 may apply an AC voltage to the probe assembly 100, and perform process monitoring through processing current flowing in the probe assembly.

Referring to FIG. 4, the plasma generator 400 may be mounted in the second region 10b. The second region 10b may be an exhaust line. Accordingly, plasma 300 generated by the plasma generator 400 may not have an effect on the first region 10a. The probe assembly 100 disposed in the second region 10b may indirectly monitor the state of the first region 10a. The plasma generator 400 disposed in the second region 10b may generate low density plasma. The plasma generator 400 may include at least one of an inductively coupled plasma generating apparatus, a capacitively coupled plasma generating apparatus, an AC plasma generating apparatus, a DC plasma generating apparatus, and an ultra high frequency plasma generating apparatus. The plasma generator may be configured to operate in at least one of continuous mode or pulse mode. For example, in the case of an ultra high frequency plasma generating apparatus, the plasma generator 400 may be disposed outside the exhaust line. Specifically, ultra high frequency may be incident through an exhaust line window to generate plasma. Thus, the geometric structure of the plasma generator 400 and the second region 10b may be varied in many ways. The probe assembly 100 is connected to the drive processor 200. The drive processor 200 may apply an AC voltage to the probe assembly 100, and perform process monitoring through processing current flowing in the probe assembly.

An optical monitoring member (not shown) may be disposed around the probe assembly 100. The optical monitoring member may analyze light generated from the plasma 300, to detect the type, density, etc., of neutral gas. Because the probe assembly 100 is mounted in the second region 10b, it can reliably extract data about the first region 10a without affecting the first region 10a. A process monitoring apparatus according to a modified embodiment of the present invention may include at least one of a plasma generator 400 disposed in a first region 10a, and a plasma generator 400 disposed in a second region 10b.

FIG. 5 is a conceptual view of a process monitoring apparatus according to an embodiment of the present invention.

Referring to FIG. 5, plasma 300 may be generated inside the process chamber 10, and the probe assembly 100 may contact the plasma 300. The drive processor 200 may apply an AC voltage having at least two fundamental frequencies to the probe assembly 100, and measure a probe current flowing through the probe assembly 100. The drive processor 200 may process the probe current to extract process monitoring parameters and display the latter on an input/output 502, and may exchange data with a host 500.

FIG. 6 is conceptual view of the drive processor 200 according to an embodiment of the present invention.

Referring to FIG. 6, the drive processor 200 may include a driver 210 that applies an AC voltage having at least two fundamental frequencies to a probe assembly 100, and a processor 220 that measures and processes a probe current flowing in the probe assembly 100 to extract process monitoring parameters. The drive processor 200 may include at least one chip or electronic board to perform the above function.

FIG. 7 is a conceptual view of a processor according to an embodiment of the present invention.

The processor 220 may include a sensor 230 for sensing a probe current flowing in a probe assembly, a frequency processor 240 for extracting the harmonic components of the respective fundamental frequencies of the probe current extracted by the sensor 230, and a data processor 250 for extracting process monitoring parameters using an output signal of the frequency processor 240. The process monitoring parameters may include at least one of components of a equivalent circuit formed by the plasma and the probe assembly, physical quantities relating to characteristics of the plasma, and physical quantities relating to the surface state of the probe electrode. The physical quantities relating to the characteristics of the plasma may include electron temperature, electron density, and ion saturation current. The components of the equivalent circuit may include equivalent capacitance, equivalent resistance, and sheath resistance. The equivalent capacitance may be modified to be an effective dielectric length.

FIG. 8 is a block diagram illustrating a data processor according to an embodiment of the present invention.

Referring to FIG. 8, the data processor 250 may receive an input of a Fourier series coefficient or a high frequency component (I_{p,n}(ω₁₀), I_{p,n}(ω₁₀)) extracted by the frequency processor 240, and may extract process monitoring parameters. Specifically, the output signals (I_{p,n}(ω₁₀), I_{p,n}(ω₁₀)) of the frequency processor 240 may be input to a DC converter 242. The DC converter 242 may convert an RMS value to a DC value. An ADC converter 251 may convert an analog output signal from the DC converter 242 to a digital signal and output the latter. A process parameter extractor 252 receives an output signal from the ADC converter 252 to extract process monitoring parameters. The process parameter extractor 252 may be controlled by a controller 254. The process parameter extractor 252 may exchange data with the input/output 502 or the host 500 through an interface 253. The interface 253 may include at least one of serial communication and parallel communication. The driver 210 may include a clock (DAC) 212 for converting a signal from the clock generator 211 to an analog signal. Output signals (A(ω₁₀), A(ω₂₀)) from the DAC 212 may be provided to the process parameter extractor 252. The output signals from the DAC 212 may be amplified by a buffer 213. Output signals (A′(ω₁₀, A′(ω₂₀)) from the buffer 213 may be applied to the probe assembly 100.

The driver 210 may be variously modified through methods other than those described above to form an AC voltage having at least 2 fundamental frequencies. The buffer 213 applies an AC voltage to the probe assembly 100. The probe current flowing in the probe assembly 100 is measured by the sensor 230. An output signal of the sensor 230 is provided to the frequency processor 240.

FIGS. 9 through 22 are diagrams illustrating a probe assembly according to an embodiment of the present invention.

Referring to FIGS. 9 through 12, the probe assembly 100 may include a probe electrode 110 and a probe support 180. The probe electrode 110 may include at least one of a discoid shape, a spherical shape, a semispherical shape, and a columnal shape. The probe electrode 110 may include at least one of a metal, a metal compound, a semiconductor, and a doped semiconductor. The probe support 180 may include a wire for applying an AC voltage to the probe electrode 110, and an insulator disposed around the wire. The sectional shape of the probe electrode may be one of a triangular shape, a rectangular shape, and a round shape. The AC applied to the probe electrode 110 may have at least two fundamental frequencies. The process of applying the AC voltage with at least two fundamental frequencies to the probe electrode 110 may include at least one of a method of continuously increasing frequencies over time, a method of applying AC voltages having mutually different frequencies at mutually different times, and a method of simultaneously applying a plurality of fundamental frequencies.

Referring to FIGS. 10 through 12, the probe assembly 100 may include a probe electrode 110 and an insulating protective layer 120 on the probe electrode 110. An AC voltage having at least two fundamental frequencies is applied to the probe electrode 110 to flow a current in the probe assembly 100. The insulating protective layer 120 may be a dielectric, so that an DC current cannot flow through the probe electrode 110, and the probe electrode 110 can be floated. Accordingly, the insulating protective layer 120 may directly or indirectly contact the plasma, and a displacement current may be made to flow in the probe electrode 110. When the insulating protective layer 120 directly contacts plasma, the plasma may act as a conductor, and the insulating protective layer 120 may perform the function of a dielectric for a capacitor. The insulating protective layer 120 may cover a portion or the entirety of the probe electrode 110. The surface of the probe electrode 110 covered by the insulating protective layer 120 may directly contact plasma. The thickness of the insulating protective layer 120 may lie in a range between about several tens of nanometers (nm) to about several tens of micrometers (um). The insulating protective layer 120 may include at least one of a metal oxide layer, a metal nitride layer, a metal oxide nitride layer, a semiconductor oxide layer, a semiconductor nitride layer, a semiconductor oxide nitride layer, a dielectric, and a polymer layer. The insulating protective layer 120 may be the same material as that on the surface of the process chamber. For example, the insulating protective layer 120 may be an aluminum oxide layer (AlO). The insulating protective layer 120 may be formed through deposition, surface treatment, etc. The insulating protective layer 110 may have a uniform thickness.

Referring to FIG. 13, the probe assembly 100 may further include a guard ring 130. The guard ring 130 may prevent interference between the probe electrode 110 and plasma. Accordingly, the guard ring 130 may be disposed to cover a portion of the probe electrode 110. A predetermined portion of the probe electrode 110 that is not covered by the guard ring 130 may be covered by the insulating protective layer 120. The guard ring 130 may be modified to various configurations according to the configuration of the probe electrode 110. The guard ring 130 may be a dielectric. The guard ring 130 may include at least one of alumina (Al₂O₃), silica (SiO₂), and glass. The guard ring 130 may have a thickness of about several tens of um.

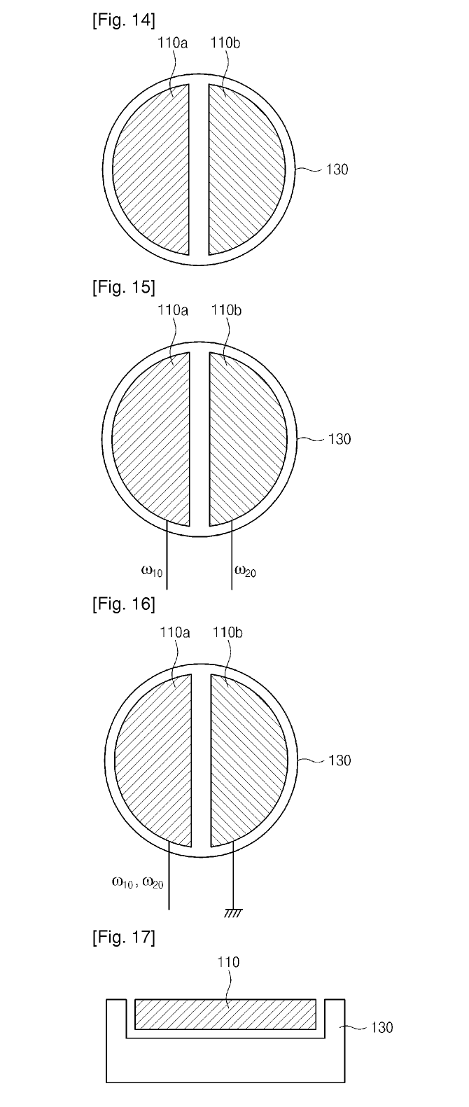

FIGS. 14 through 16 are diagrams illustrating a cylindrical probe assembly including a plurality of probe electrodes.

Referring to FIGS. 14 through 16, a probe assembly 100 may include a plurality of probe electrodes 110a and 110b. The probe electrode 110 may include a first probe electrode 110a and a second probe electrode 110b. Referring to FIG. 14, the first probe electrode 110a and the second probe electrode 110b may be disposed on one guard ring 130. The first probe electrode 110a and the second probe electrode 110b may be disposed apart to be insulated from one another. An insulating protective layer (not shown) may be disposed on the probe electrode 110. The probe assembly 100 may include 3 or more probe electrodes.

Referring to FIG. 15, a first fundamental frequency may be applied to a first probe electrode 110a, and a second fundamental frequency may be applied to a second probe electrode 110b.

Referring to FIG. 16, a first fundamental frequency and a second fundamental frequency may be applied simultaneously or at different times to the first probe electrode 110a, and the second probe electrode 110b may be grounded.

FIGS. 17 through 22 are diagrams illustrating a configuration of a probe assembly according to an embodiment of the present invention.

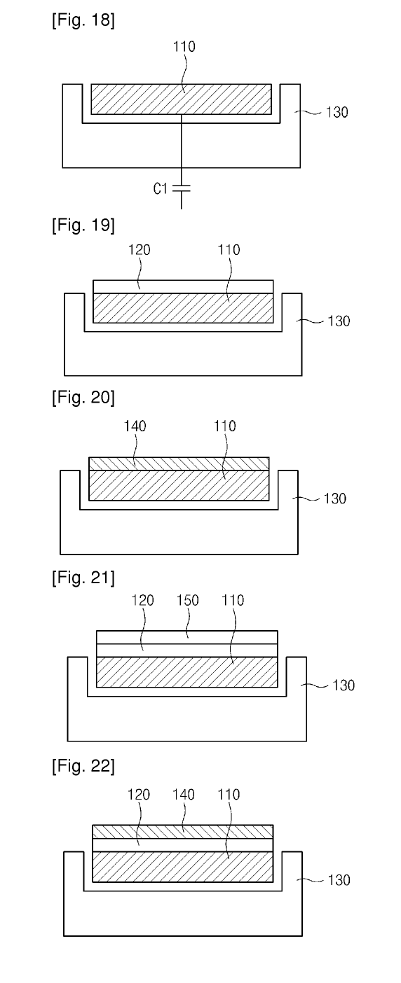

Referring to FIG. 17, a probe assembly 100 may include a probe electrode 110 and a guard ring 130. The probe electrode 110 may directly contact plasma. Referring to FIG. 18, the probe assembly 100 may further include a capacitor (C1) between the probe electrode 110 and a driver (not shown). The probe electrode 110 may be floated by the capacitor (C1).

Referring to FIG. 19, the probe assembly 100 may further include an insulating protective layer 120 covering the entirety or a portion of the probe electrode 110. The insulating protective layer 120 may be a dielectric.

Referring to FIG. 20, a probe assembly 100 may have a conductive thin film 140 formed on a probe electrode 110 during processing. The conductive thin film 140 may be a conductive material formed in a physical vapor deposition (PVD) or a chemical vapor deposition (CVD) process for depositing a conductive material on a substrate. The conductive thin film 140 may include at least one of a metal, a metal silicide, a metal compound, and a doped semiconductor. The conductive thin film 140 may have permittivity. Accordingly, the conductive thin film 140 may have a capacitance and a resistance. The conductive thin film 140 may be amorphous, and may include dopants.

Referring to FIG. 21, a probe assembly 100 of the present invention may include a dielectric thin film 150 formed on the insulating protective layer 120 during processing. The dielectric thin film 150 may include at least one of a polymer film, a semiconductor oxide film, a semiconductor nitride film, a semiconductor oxide nitride film, a metal oxide film, and an high k film. The dielectric thin film 150 may be formed in an etch process or a deposition process. Also, the dielectric thin film 150 may be formed in a CVD process that does not employ plasma. Specifically, the polymer film may be a CF-based polymer generated in an etch process. The high k film may be an aluminum oxide film, a zirconium oxide film, a tantalum oxide film, or a hafnium oxide film. The high k film may be a material formed in a deposition process inside a process chamber.

Referring to FIG. 22, a probe assembly 100 may have an insulating protective layer 120 and a conductive thin film 140 formed on a probe electrode 110. According to a modified embodiment of the present invention, the material formed on the probe electrode may be varied.

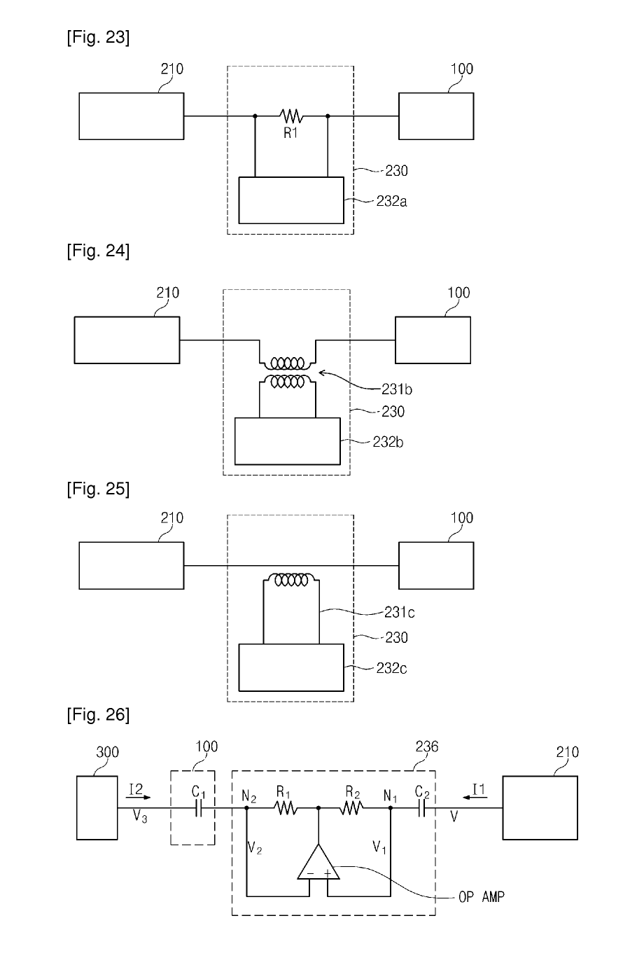

FIGS. 23 through 25 are block diagrams illustrating a sensor according to an embodiment of the present invention.

Referring to FIG. 23, an AC voltage formed at a driver 210 is applied to the probe assembly 100, and a probe current flowing in the probe assembly 100 is measured through the sensor 230. The sensor 230 may employ a measured resistance (R₁) to measure the current. The measured resistance (R₁) may be a value less than the above-described sheath resistance (Rsh). Specifically, the measured resistance (R₁) may be about several hundred ohms or less. A voltage difference at either end of the measured resistance (R₁) may be proportional to the current flowing through the measured resistance (R₁). The voltage difference at either end of the measured resistance (R₁) may be amplified by an amplifier 232a.

Referring to FIG. 24, the sensor 230 may employ a transformer to measure a probe current flowing in the probe assembly 100. An output signal of the transformer 231b may be amplified through an amplifier 232b.

Referring to FIG. 25, a sensor 230 may employ a coil assembly 231c to measure a probe current flowing in a probe assembly 100. An output signal of the coil assembly 231c may be amplified through an amplifier 232c.

FIG. 26 is a diagram illustrating a compensator for calibrating a measurement signal of a sensor according to an embodiment of the present invention.

When a probe assembly 100 includes an insulating protective layer, or a capacitor is included between the probe assembly 100 and a driver 210, there is a need to compensate for a capacitance through the insulating protective layer or the capacitor. For example, when the capacitor is included, a voltage difference may occur between a voltage applied by the driver 210 and a voltage applied to plasma 300.

Referring to FIG. 26, a description will be given of when an insulating protective layer 120 is formed on the probe electrode 110. To extract data of a thin film formed on the probe electrode 110, a capacitance (C₁) formed by the insulating protective layer on the probe electrode 110 must be removed. Referring to FIG. 26, V represents an output voltage of a driver 210, and C₁ represents the capacitance formed by the insulating protective layer 120. The capacitance (C₁) and the measured resistance (R₁) are disposed in series by an insulating protective layer between the driver 210 and plasma 300. A compensation resistor (R₂) and a compensation capacitor (C₂) are disposed in series symmetricallyimpeured resistance (R₁) and the capacitance (C₁) formed by the insulating protective layer. An output end of an operation amplifier (OP AMP) is connected between the measured resistance (R₁) and the compensation resistor (R₂). The negative input end of the OP AMP is connected between the measured resistance (R₁) and the capacitance (C₁) formed by the insulating protective layer, and the positive input end of the OP AMP is connected between the compensation resistor (R₂) and the compensation capacitor (C₂). As devices that compensate for voltage drops of (R₁) and (C₁), (R₂) and (C₂) have the same impedances as (R₁) and (C₁), respectively. When the driver 210 generates a signal (V), a voltage (V₁) is applied to a node 1 (N1), a voltage (V₂) is applied to a node 2 (N2), and a potential of plasma becomes (V₃). A current (I₂) flows in the node 2 (N2) due to a potential difference between (V₃) and (V₂), and the current (I₂) may flow through the resistance (R₁) to the OP AMP. In this case, voltages (V₂) and (V₁) must be the same, and the current (I₁) that is the same as the current (I₂) flowing through the resistance (R₁) flows through the resistor (R₂). That is, the output of the OP AMP is determined at the point when the (I₂) and (I₁) become the same. Here, (I₂) and (I₁) are the same in size, and (V₁) and (V₂) become the same, so that the voltage drops in (C₁) and (C₂) become the same. Accordingly, at the point when (V₃) and (V) become the same, the OP AMP becomes stable. Through this method, the voltage drop of the capacitance (C₁) can be compensated by the insulating protective layer 120. The configuration of a compensator 236 of the present invention may be modified to various different forms.

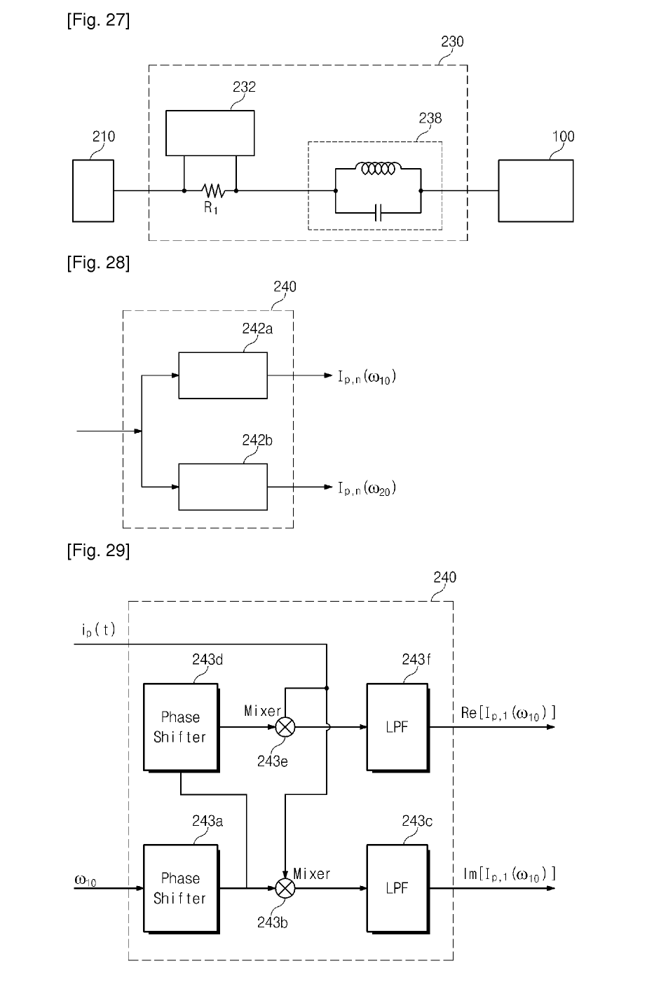

FIG. 27 is a circuit diagram illustrating a filter for removing noise according to an embodiment of the present invention.

Referring to FIG. 27, a sensor 230 is disposed between a driver 210 and a probe assembly 100. The sensor 230 may include a filter 238. The filter 238 may include a choke filter for removing noise that enters from plasma. Specifically, plasma may be generated by an RF power, where the driving frequency of the RF power can affect the potential of the plasma. Therefore, the sensor 230 may include the filter 238 to prevent the driving frequency components of the RF power from being measured at the measured resistance (R₁) of the sensor 230. The filter 238 may be a band pass filter or a low frequency pass filter. The filter 238 may transmit the fundamental frequencies of the driver 210 and the harmonics thereof, and may block the driving frequency components of the RF power. The filter 238 may be formed through a passive device or an active device.

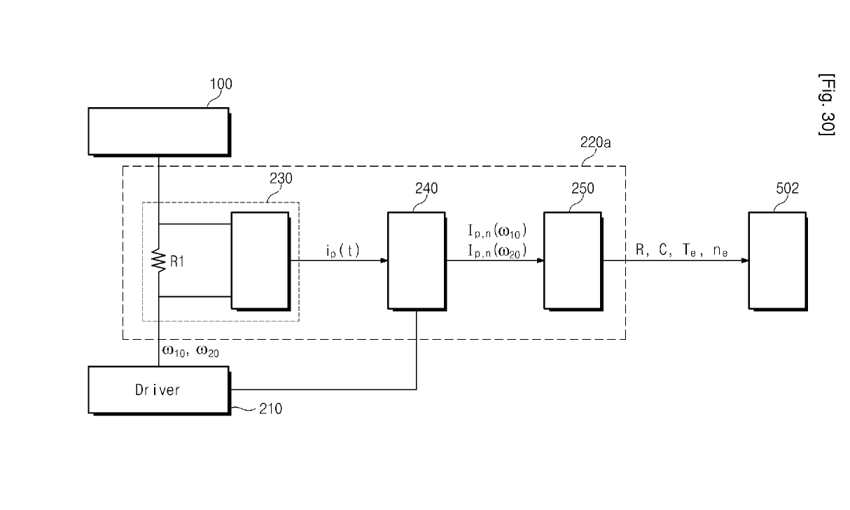

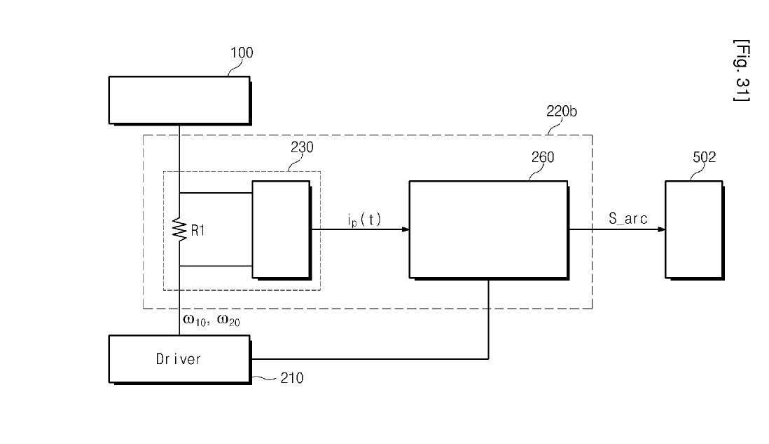

FIGS. 28 and 29 are diagrams illustrating a frequency processor according to an embodiment of the present invention.

Referring to FIG. 28, an AC voltage applied to the probe assembly 100 has at least 2 fundamental frequencies. Therefore, a probe current (iₚ(t)) flowing in the probe assembly 100 may include the fundamental frequency components. However, the probe current may have a waveform different than that of the applied voltage. Accordingly, the probe current may be expanded through a Fourier series with respect to each fundamental frequency.

A Fourier series coefficient may be extracted through a Fourier transformer. The Fourier transformer may receive an input digital signal and output the signal through fast Fourier transformation (FFT). The Fourier transformer may be embodied as a chip. The frequency processor 240 may include the Fourier transformer.

Referring to FIG. 28, the Fourier series coefficient may be extracted through a band pass filter. A fundamental frequency may include a first fundamental frequency and a second fundamental frequency. The frequency processor may include a first frequency processor 242a that extracts a Fourier series coefficient of the first fundamental frequency, and a second frequency processor 242b that extracts a Fourier series coefficient of the second fundamental frequency. The first frequency processor 242a and the second frequency processor 242b may extract a DC Fourier series coefficient, a first Fourier series coefficient, and a second Fourier series coefficient.

Referring to FIG. 29, the probe current (iₚ(t)) of the probe assembly 100 may include at least two fundamental frequency components. The frequency processor 240 may include a lock in detector. In detail, a first phase shifter 243a receives an input sine wave having a first fundamental frequency, and shifts the phase. A first mixer 243b receives an input of an output signal of the first phase shifter 243a and the probe current, and multiplies and outputs the two signals. A first frequency pass filter 243c may extract an imaginary component of the first Fourier series coefficient of the first fundamental frequency in the output signal of the first mixer 243b. Also, a second phase shifter 243d receives an input of an output signal of the first phase shifter 243a to shift the phase. A second mixer 243e receives an input of an output signal of the second phase shifter 243d and the probe current, and multiplies and extracts the two signals. A second low frequency pass filter 243f may extract an error component of the first Fourier series coefficient of the first fundamental frequency from an output signal of the second mixer 243e. The frequency processor 240 may be similarly applied in order to extract the second Fourier series coefficient. Also, the frequency processor 240 may be similarly applied with respect to the second fundamental frequency.

FIG. 30 is a block diagram illustrating a process monitoring apparatus according to an embodiment of the present invention.

Referring to FIG. 30, a process monitoring apparatus may include a probe assembly 100, a driver 210, and a processor 220a. The driver 210 applies an AC voltage having at least 2 fundamental frequencies to the probe assembly 100. The processor 220a may include a sensor 230, a frequency processor 240, and a data processor 250. The sensor 230 may measure a probe current (iₚ(t)) flowing in the probe assembly 100 through a measured resistance (R1). The frequency processor 240 may extract a Fourier series coefficient using at least one of the above-described Fourier transformer, filter, and lock in detector. The data processor 250 may use the Fourier series coefficient to extract process monitoring parameters. The process monitoring parameters may include at least one of an equivalent capacitance (C) between the probe assembly 100 and plasma 300, a sheath resistance (Rsh), an electron temperature (Te), and an electron density. An input/output 502 may display the process monitoring parameters.

FIG. 31 is a block diagram illustrating a process monitoring apparatus according to another embodiment of the present invention.

A description will be provided of a process monitoring apparatus for determining arc discharge, according to another embodiment of the present invention. An electric potential of plasma is the plasma potential. The plasma potential may have a uniform value or a periodic value in a stable state. However, if an arc is discharged in plasma, the plasma potential can suddenly change. A plasma potential corresponding to an arc discharge can spontaneously change a probe current flowing in a probe assembly 100. Accordingly, changes in a probe current in a probe assembly 100 can be measured to determine whether there are arc discharges. The current flowing in the probe assembly may include a displacement current. In this case, the current flowing in the probe assembly may be dependent on an equivalent capacitance of the probe assembly 100. When the probe current deviates from a normal state, it can be determined that an arc discharge has occurred.

Referring to FIG. 31, a process monitoring apparatus may include a probe assembly 100, a driver 210, and a processor 220b. The driver 210 applies an AC voltage having at least 2 fundamental frequencies to the probe assembly 100. The processor 220b may include a sensor 230 and an arc processor 260. The sensor 230 may measure a probe current (iₚ(t)) flowing in the probe assembly 100 through a measured resistance (R1). The arc processor 260 may be configured to detect whether the probe current (iₚ(t)) deviates from a normal state. The arc processor 260 may determine whether an arc is discharged and may output an arc discharge signal (S_arc). An input/output 502 may receive an input of the arc discharge signal (S_arc), and display the same. For example, the probe current may be Fourier transformed to perform a comparison with normal amplitudes of first Fourier series coefficients of the respective fundamental frequencies to determine whether there is arc discharge.

A description will be provided of an end-point detection of an etch process according to another embodiment of the present invention. In an etch process using plasma, because the constituents of gas in a process chamber are altered when an etch stop layer is exposed, the characteristics of plasma may be altered. Such alterations in plasma characteristics may be detected through the process monitoring apparatus to perform end-point detection of etching.

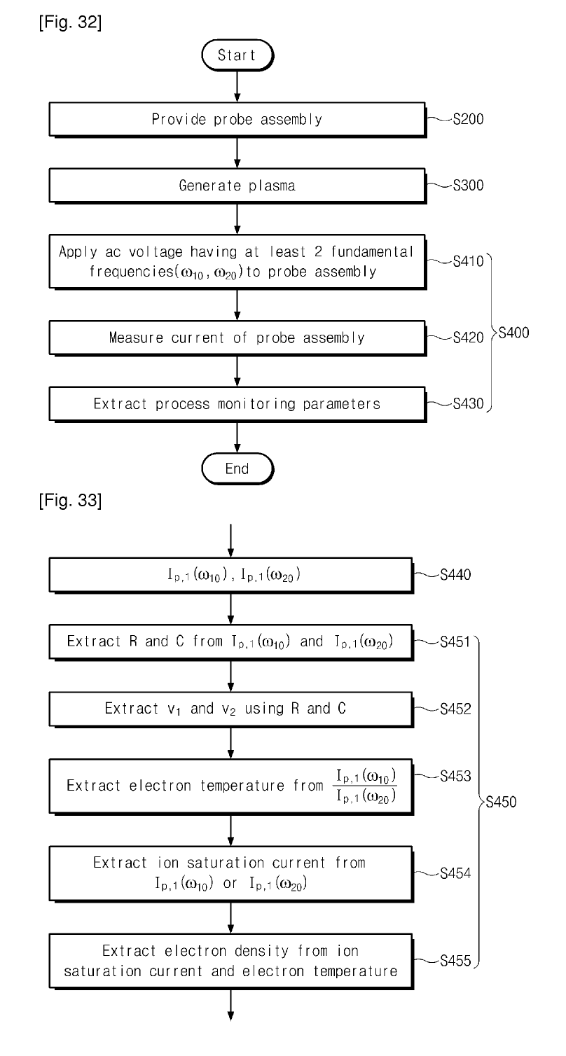

FIG. 32 is a flowchart illustrating a process monitoring method according to an embodiment of the present invention.

Referring to FIG. 32, a process monitoring method includes providing a probe assembly including a probe electrode in a process chamber in which a process is performed, in operation S200. In operation S300, plasma is generated around the probe assembly, and in operation S400, an AC voltage having at least 2 fundamental frequencies is applied to the probe assembly, and process monitoring parameters are extracted.

The processing performed in the process chamber may be a process that uses plasma, or may be a process that does not use plasma. The probe assembly, as described above, may have a plurality of thin films formed on the probe electrode. The probe assembly may be disposed on the process chamber or an exhaust line. The plasma may include at least one of an inductively coupled plasma, a capacitively coupled plasma, a DC plasma, and an ultra high frequency plasma.

The operation S400 of extracting the process monitoring parameters may include an operation S410 in which an AC voltage having at least two fundamental frequencies is applied to the probe electrode, an operation S420 in which a probe current flowing in the probe electrode is extracted, and an operation S430 in which harmonic components for the respective fundamental frequencies of the probe current flowing in the probe electrode are extracted, and the components are processed to extract process monitoring parameters.

The process monitoring parameters may include at least one of equivalent circuits formed by the plasma and the probe assembly, components relating to characteristics of the plasma, and physical quantities relating to the surface condition of the probe electrode.

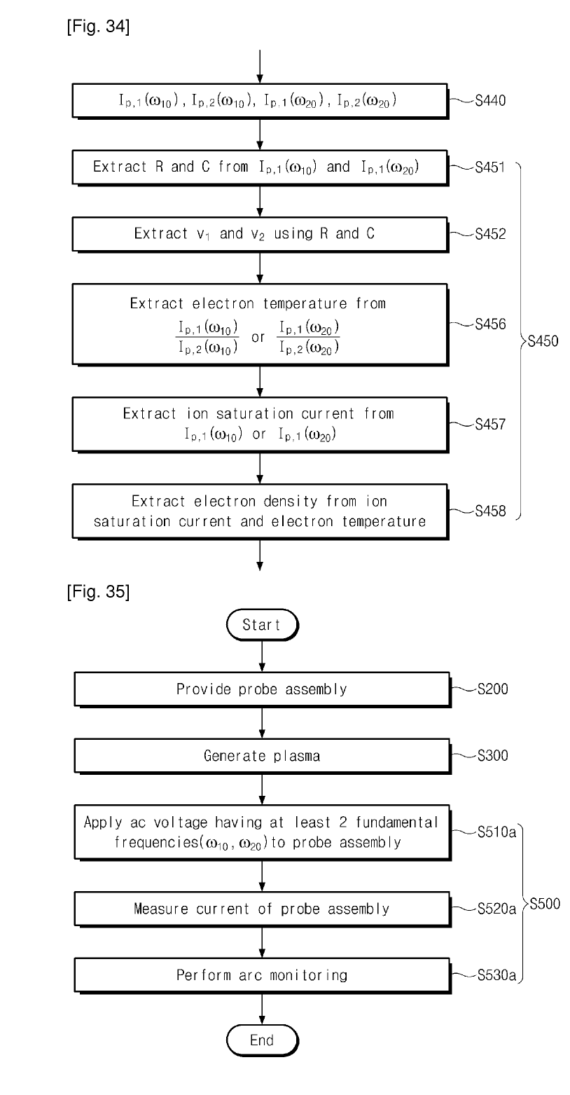

FIGS. 33 and 34 are flowcharts illustrating process monitoring methods according to an embodiment of the present invention.

Referring to FIGS. 33 and 34, a process monitoring method according to an embodiment of the present invention may include an operation S400 for extracting process monitoring parameters. The operation S400 of extracting the process monitoring parameters may include an operation S440 in which an AC current including a first fundamental frequency and a second fundamental frequency is applied, and a Fourier series coefficient of the first fundamental frequency of the probe current and a Fourier series coefficient of the second fundamental frequency of the probe current are extracted; and an operation S450 in which the Fourier series coefficient of the first fundamental frequency and the Fourier series coefficient of the second fundamental frequency are used to extract the process monitoring parameters.

According to an embodiment of the present invention, an operation S450 of using the Fourier coefficient to extract the process monitoring parameters may extract the process monitoring parameters through using a first Fourier series coefficient of the first fundamental frequency and a first Fourier series coefficient of the second fundamental frequency. Specifically, equivalent circuit components are extracted in operation S451 through using the first Fourier series coefficient of the first fundamental frequency and the first Fourier series coefficient of the second fundamental frequency. In operations S453 and S454, physical quantities relating to the characteristics of the plasma may be extracted through using the first Fourier series coefficient of the first fundamental frequency and the first Fourier series coefficient of the second fundamental frequency. In detail, in operation S451, an equivalent capacitance (C) and a sheath resistance (Rsh) are extracted through using the first Fourier series coefficient of the first fundamental frequency and the first Fourier coefficient of the second fundamental frequency. In operation S452, the equivalent capacitance (C) and the sheath resistance (Rsh) may be used to obtain v1 and v2. In operation S453, v1 and v2 may be used to obtain an electron temperature. In operation S454, the electron temperature may be used to obtain an ion saturation current. In operation S455, the ion saturation current and the electron temperature may be used to obtain an electron density.

Referring to FIG. 34, an operation S450 according to a modified embodiment of the present invention that uses the Fourier series coefficient of the first fundamental frequency and the Fourier series coefficient of the second fundamental frequency to extract the process monitoring parameters may include operation S451 in which equivalent circuit components are extracted through using a first Fourier series coefficient of the first fundamental frequency and a first Fourier series coefficient of the second fundamental frequency. In operations S456, S457, and S458, physical quantities relating to characteristics of the plasma may be extracted through using a first Fourier series coefficient of the first fundamental frequency and a second Fourier series coefficient of the first fundamental frequency, or a first Fourier series coefficient of the second fundamental frequency and a second Fourier series coefficient of the second fundamental frequency. Specifically, in operation S451, an equivalent capacitance (C) and a sheath resistance (Rsh) may be extracted through using a first Fourier series coefficient of the first fundamental frequency and a first Fourier series coefficient of the second fundamental frequency. In operation S452, v1 and v2 may be obtained through using the equivalent capacitance (C) and the sheath resistance (Rsh). In operation S456, v1 and v2 may be used to obtain an electron temperature. As described in equation 16, electron temperature may be a function of the first Fourier series coefficient of the first fundamental frequency and the second Fourier series coefficient of the first fundamental frequency. Also, the electron temperature may be a function of the first Fourier series coefficient of the second fundamental frequency and the second Fourier series coefficient of the second fundamental frequency. In operation S457, an ion saturation current may be obtained through using the electron temperature. In operation S458, an electron density may be obtained through using the ion saturation current and the electron temperature.

FIG. 35 is a flowchart illustrating a process monitoring method according to an embodiment of the present invention.

Referring to FIG. 35, a process monitoring method according to an embodiment of the present invention includes an operation S200 in which a probe assembly including a probe electrode is provided to a process chamber in which a process is performed, an operation S300 in which plasma is generated around the probe electrode, and an operation S500 in which an AC voltage having at least 2 fundamental frequency components is applied to the probe assembly, and process monitoring parameters are extracted. The operation S500 in which the process monitoring parameters are extracted may include an operation S510a in which an AC current having at least 2 fundamental frequencies is applied to the probe assembly, an operation S520a in which a probe current flowing in the probe assembly is extracted, and an operation S530a in which it is determined that an arc discharge has occurred when the probe current deviates from a normal state.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A process monitoring apparatus comprising:
a process chamber in which a process is performed;
a probe assembly disposed on the process chamber, and comprising a probe electrode;
a plasma generator generating plasma around the probe assembly; and
a drive processor applying an alternating current (AC) voltage having at least 2 fundamental frequencies to the probe assembly, and extracting process monitoring parameters.

2. The process monitoring apparatus of claim 1, wherein the drive processor comprises:
a driver applying an AC voltage having at least 2 fundamental frequencies to the probe electrode;
a sensor measuring a probe current flowing in the probe electrode; and
a processor extracting harmonic components of each fundamental frequency of the probe current,
wherein the processor processes the harmonic components of each of the fundamental frequencies to extract process monitoring parameters.

3. The process monitoring apparatus of claim 2, wherein the process monitoring parameters comprise at least one of components of equivalent circuits formed by the plasma and the probe assembly, physical quantities relating to characteristics of the plasma, and physical quantities relating to a surface state of the probe electrode.

4. The process monitoring apparatus of claim 3, wherein the fundamental frequencies of the AC voltage comprise a first fundamental frequency and a second fundamental frequency,
the processor comprising:
a frequency processor configured to extract a Fourier series coefficient of the first fundamental frequency of the probe current and a Fourier series coefficient of the second fundamental frequency of the probe current; and
a data processor configured to extract the process monitoring parameters through using the Fourier series coefficient of the first fundamental frequency and the Fourier series coefficient of the second fundamental frequency.

5. The process monitoring apparatus of claim 4, wherein the data processor extracts the process parameters through using a first Fourier series coefficient of the first fundamental frequency and a first Fourier coefficient of the second fundamental frequency.

6. The process monitoring apparatus of claim 4, wherein the data processor is configured to extract the equivalent circuit components through using the first Fourier series coefficient of the first fundamental frequency and the first Fourier series coefficient of the second fundamental frequency, and is configured to extract the physical quantities relating to the characteristics of the plasma through using the first Fourier series coefficient of the first fundamental frequency and a second Fourier series coefficient of the first fundamental frequency, or the first Fourier series coefficient of the second fundamental frequency and a second Fourier series coefficient of the second fundamental frequency.

7. The process monitoring apparatus of claim 4, wherein the data processor is configured to extract the equivalent circuit components through using the first Fourier series coefficient of the first fundamental frequency and the first Fourier series coefficient of the second fundamental frequency, and is configured to extract the physical quantities relating to the characteristics of the plasma through using the first Fourier series coefficient of the first fundamental frequency and the first Fourier series coefficient of the second fundamental frequency.

8. The process monitoring apparatus of claim 2, wherein:
the probe assembly further comprises an insulating protective layer that separates the probe electrode from the plasma; and
the sensor further comprises a compensator that compensates for a capacitance of the insulating protective layer in terms of a circuit.

9. The process monitoring apparatus of claim 1, wherein the drive processor comprises:
a driver applying an AC voltage having at least two fundamental frequencies to the probe electrode;
a sensor measuring a probe current flowing in the probe electrode; and
an arc processor processing the probe current and determining whether an arc is discharged in the plasma.

10. The process monitoring apparatus of claim 1, wherein the drive processor is configured to extract at least one of a capacitance and a sheath resistance between the probe assembly and the plasma.

11. The process monitoring apparatus of claim 1, further comprising at least one of a capacitor between the probe assembly and the drive processor, and an insulating protective layer on the probe electrode.

12. The process monitoring apparatus of claim 1, wherein the probe assembly comprises a first probe electrode and a second probe electrode,
wherein a first fundamental frequency is applied to the first probe electrode, and a second fundamental frequency is applied to the second probe electrode.

13. The process monitoring apparatus of claim 1, wherein the probe assembly comprises a first probe electrode and a second probe electrode,
wherein a first and a second fundamental frequency are applied to the first probe electrode, and the second probe electrode is grounded.

14. The process monitoring apparatus of claim 1, wherein the drive processor is configured to monitor a change in process monitoring parameters through a thin film formed on the probe electrode.

15. The process monitoring apparatus of claim 1, wherein the process chamber comprises a first region in which a process is performed and a second region connected to an exhaust pump, and the plasma generator generates plasma in the first region or the second region.

16. The process monitoring apparatus of claim 1, wherein an AC voltage having at least 2 fundamental frequencies is applied to the probe electrode using at least one of a method of increasing a frequency continuously over time, a method of applying AC voltages comprising respectively different frequencies at respectively different points in time, and a method of simultaneously applying a plurality of fundamental frequencies.

17. A process monitoring method comprising:
providing a probe assembly comprising a probe electrode to a process chamber;
generating plasma around the probe assembly; and
applying an alternating current (AC) voltage having at least two fundamental frequencies to the probe assembly, and extracting process monitoring parameters.

18. The process monitoring method of claim 17, wherein the extracting of the process monitoring parameters comprises:
applying an AC voltage having at least two fundamental frequencies to the probe electrode;
measuring a probe current flowing in the probe electrode; and
extracting harmonic frequencies of respective fundamental frequencies of the probe current flowing in the probe electrode, and processing the harmonic frequencies to extract process monitoring parameters.

19. The process monitoring method of claim 18, wherein the process monitoring parameters comprise at least one of components of equivalent circuits formed by the plasma and the probe assembly, physical quantities relating to characteristics of the plasma, and physical quantities relating to a surface state of the probe electrode.

20. The process monitoring method of claim 19, wherein the fundamental frequencies of the AC voltage comprise a first fundamental frequency and a second fundamental frequency, and
the extracting of the process monitoring parameters comprises:
extracting a Fourier series coefficient of the first fundamental frequency of the probe current and a Fourier series coefficient of the second fundamental frequency of the probe current; and
extracting the process monitoring parameters through using the Fourier series coefficient of the first fundamental frequency and the Fourier series coefficient of the second fundamental frequency.

21. The process monitoring method of claim 20, wherein the extracting of the process monitoring parameters through using the Fourier series coefficient of the first fundamental frequency and the Fourier series coefficient of the second fundamental frequency comprises
extracting the process monitoring parameters through using a first Fourier series coefficient of the first fundamental frequency and a first Fourier coefficient of the second fundamental frequency.

22. The process monitoring method of claim 20, wherein the extracting of the process monitoring parameters through using the Fourier series coefficient of the first fundamental frequency and the Fourier series coefficient of the second fundamental frequency comprises:
extracting the equivalent circuit components through using the first Fourier series coefficient of the first fundamental frequency and a second Fourier series coefficient of the first fundamental frequency; and
extracting the physical quantities relating to the characteristics of the plasma through using the first Fourier series coefficient of the second fundamental frequency and a second Fourier series coefficient of the second fundamental frequency.

23. The process monitoring method of claim 20, wherein the extracting of the process monitoring parameters through using the Fourier series coefficient of the first fundamental frequency and the Fourier series coefficient of the second fundamental frequency comprises:
extracting the equivalent circuit components through using the first Fourier series coefficient of the first fundamental frequency and the first Fourier series coefficient of the second fundamental frequency; and
extracting the physical quantities relating to the characteristics of the plasma through using the first Fourier series coefficient of the first fundamental frequency and the first Fourier series coefficient of the second fundamental frequency.

24. The process monitoring method of claim 17, wherein the extracting of the process monitoring parameters comprises processing a probe current flowing in the probe assembly to determine an end point of an etching.

25. The process monitoring method of claim 17, wherein the extracting of the process monitoring parameters comprises processing a probe current flowing in the probe assembly, and treating a deviation of the probe current from a normal state as an arc discharge.

26. A process monitoring apparatus comprising:
a probe assembly comprising a probe electrode; and
a drive processor for applying an alternating current (AC) voltage having at least 2 fundamental frequencies to the probe assembly, and extracting process monitoring parameters.

27. The process monitoring apparatus of claim 26, wherein the drive processor comprises:
a driver applying an AC voltage having at least 2 fundamental frequencies to the probe electrode;
a sensor for measuring a probe current flowing in the probe electrode; and
a processor for extracting harmonic components for each of the fundamental frequencies of the probe current, wherein the processor processes the harmonic components for the respective fundamental frequencies to extract the process monitoring parameters.

28. The process monitoring apparatus of claim 26, further comprising at least one of a capacitor between the probe assembly and the drive processor, and an insulating protective layer on the probe electrode.
